(19) United States
(12) Patent Application Publication
(10) Pub. No.: US 2004/0164384 A1
(43) Pub. Date: Aug. 26, 2004

(54) Surface excited device package including a substrate having a vibration-permitted cavity

(76) Inventors: Byoung Youl Min, Seoul (KR); Choon Heung Lee, Seoul (KR); Seon Goo Lee, Kyonggi-do (KR)

Correspondence Address: WEISS & MOY PC, 4204 NORTH BROWN AVENUE, SCOTTSDALE, AZ, 85251, US

(21) Appl. No.: 10/147,239

(22) Filed: May 14, 2002

(51) Int. Cl. H01L 23/02

(52) U.S. Cl. 257/678

(57) ABSTRACT

A surface excited device package and method for packaging a surface excited device provide a surface excited device having a small footprint, high reliability, low cost and high production volume. The surface excited device may be a Surface Acoustic Wave (SAW) device or a Micro Electromechanical System(MEMS) device. A substrate including multiple conductive patterns is bonded to a semiconductor die that includes a surface excited device area. The substrate includes multiple conductive patterns for connecting electrical connections of the die and terminals for connecting the surface excited device to external devices. The substrate further includes an aperture over the surface exited device area and a cover for covering the cavity formed by the aperture to protect the surface excited device area from the external environment.

### FIELD OF THE INVENTION

The present invention relates generally to integrated circuit packaging and more specifically, to packaging methods and assemblies for packaging surface excited devices.

### BACKGROUND OF THE INVENTION

Surface excited piezoelectric devices such as Surface Acoustic Wave (SAW) devices and Micro Electro-Mechanical System (MEMS) devices are commonly used in electronic and electromechanical/electro-optical systems. Other piezoelectric transducers are in common use for buzzers, crystal oscillators and filters, and other applications.

SAW devices provide a bandpass filter or comb filter function by converting electric signals into a surface acoustic wave, i.e. mechanical signal, through a substrate. The electrodes are inter-digitally arranged on a substrate and a piezoelectric effect generates acoustic waves on the surface of the substrate. Frequency and phase control is achieved through the design of the circuit electrodes.

MEMS devices include miniature electromechanical actuators formed from individual piezoelectric elements formed on a substrate. They are used to position miniature mirrors and other optical components to form electro-optical systems as well as for other micro-mechanical systems.

Surface excited devices provide advantages in high integration, low power, high reliability and low cost applications. Since the manufacturing process is similar to that for semiconductor processing, the device can be manufactured in groups on a wafer. Further, a plurality of surface excited devices, signal processing components and other electronic structures can be integrated within one semiconductor die, resulting in high efficiency, low cost, high reliability and high production volumes.

In accordance with the recent trend of most electronic, mechanical and optical components towards more compact, high performance and low cost designs, the surface excited device has found application as a core technology within the fields of bio- technology, communication & information processing, transportation & aerospace, optics, robotics and others.

However, in conventional semiconductor packaging, the substrate is much larger than the die and a surface excited device is much larger than a typical semiconductor die. Therefore, conventional semiconductor packaging of a surface excited device will result in a very large package.

Further, as wire bonding, solder bump addition, encapsulating and other processes are conducted after the semiconductor dies are singulated, the larger package reduces the semiconductor package assembly throughput and increases the assembly cost.

Therefore, it would be desirable to provide a package for a surface excited device having a reduced substrate area.

### SUMMARY OF THE INVENTION

The above stated objectives are achieved in a surface excited device package and a method for packaging a surface excited device. The device package includes a die including a surface excited device area and a substrate bonded to a surface of the die and including multiple conductive patterns. The substrate further defines a cavity the surface exited device area and the device package further includes multiple conductive connectors for connecting the conductive patterns of the substrate to the electrical terminals of the die.

### BRIEF DESCRIPTION OF THE DRAWINGS

FIG. 1A is a sectional view illustrating a surface excited device according to an embodiment of the present invention;

FIG. 1B is a plan view illustrating a surface excited device according to an embodiment of the present invention;

FIG. 2 is a sectional view illustrating a surface excited device according to another embodiment of the present invention;

FIG. 3 is a sectional view illustrating a surface excited device according to another embodiment of the present invention;

FIG. 4 is a sectional view illustrating a surface excited device according to another embodiment of the present invention;

FIG. 5 is a sectional view illustrating a surface excited device according to another embodiment of the present invention;

FIG. 6 is a sectional view illustrating a surface excited device according to another embodiment of the present invention;

FIG. 7A through FIG. 7F are pictorial diagrams depicting a method for manufacturing a surface excited device in accordance with an embodiment of the present invention;

FIG. 8A through FIG. 8F are pictorial diagrams depicting a method for manufacturing a surface excited device in accordance with another embodiment of the present invention;

FIG. 9A through FIG. 9E are pictorial diagrams depicting a method for manufacturing a surface excited device in accordance with another embodiment of the present invention; and

FIG. 10A through FIG. 10D are pictorial diagrams depicting a method for manufacturing a surface excited device in accordance with another embodiment of the present invention.

The invention, as well as a preferred mode of use and advantages thereof, will best be understood by reference to the following detailed description of illustrative embodiments when read in conjunction with the accompanying drawings, wherein like reference numerals indicate like parts throughout.

### DETAILED DESCRIPTION

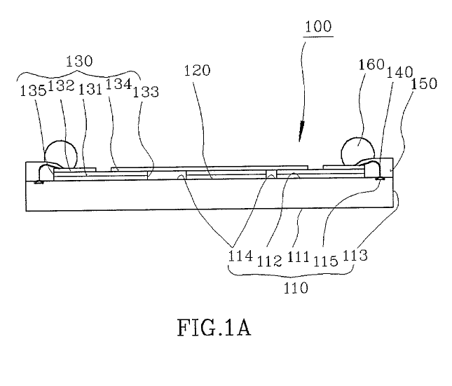

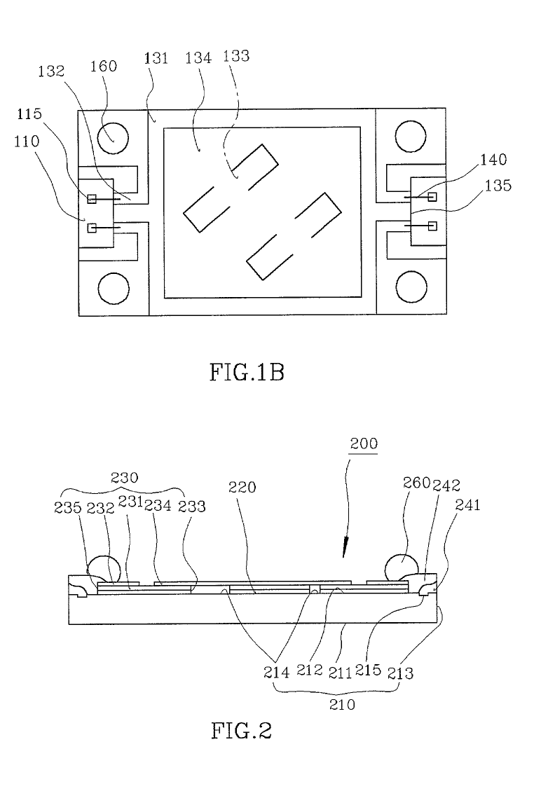

Referring to FIG. 1A and FIG. 1B, a surface excited device 100 according to the present invention is illustrated. An encapsulating portion 150 shown in FIG. 1A is omitted in FIG. 1B to provide a view of underlying features.

As shown in the drawings, a semiconductor die 110 having a substantially planar first surface 111 and second surface 112 and side surfaces 113, includes an surface excited device area 114 on second surface 112. Surface excited device area 114 is generated with three-dimensional structures formed by a SAW technique or a MEMS technique. A plurality of input and output bond pads 115 are formed at the circumference of second surface 112 in the vicinity of the side surface 113. The actual three-dimensional structures forming the surface excited device are not illustrated in FIG. 1A and FIG. 1B.

An approximately planar substrate 130 is bonded to second surface 112 of semiconductor die 110 by an adhesive 120. Substrate 130 comprises a flexible insulating layer 131 bonded to adhesive 120 and a plurality of conductive patterns 132 formed on flexible insulating layer 131.

Adhesive 120 may be a conventional double-sided adhesive tape and flexible insulating layer 131 may be a nonconductive polyimide or other insulating material such as flame retardant (FR) material FR-5, and conductive patterns 132 are formed from a conductive material such as copper foil. At least one cavity 133 is formed within a region of substrate 130 corresponding to surface excited device area 114 of semiconductor die 110 by an i aperture through insulating layer 131 and adhesive 120. Cavity 133 is covered with a cover 134 to protect surface excited device area 114 from the external environment. Cover 134 may be made from the same material as conductive patterns 132 (e.g., copper foil) or alternatively may be made from a different material applied to insulating layer 131.

A slot 135 of predetermined size is formed at a region of adhesive 120 and substrate 130 corresponding to the input and output bond pads 115 of semiconductor die 110. Semiconductor die 110 and substrate 130 are identical in length and width, with the exception of slot 135 region. Substrate 130 does not extend beyond side surface 113 of semiconductor die 110.

Input and output bond pads 115 of semiconductor die 110 are electrically and mechanically connected to conductive patterns 132 of the substrate 130 by conductive wires 140, such as gold (Au) or aluminum (Al) wire. Further, input and output bond pads 115, conductive wire 140, a portion of conductive patterns 132 and slot 135 are encapsulated by an encapsulant 150 to protect them from the external environment. The side surface of encapsulant 150 is flush with side surface 113 of semiconductor die 110. Accordingly, the area of the entire surface excited device package is no larger than the area of semiconductor die 110. A plurality of conductive balls 160 are fused to the conductive patterns 132 to form terminals for connecting the packaged surface excited device to an external device. Thus a conductive path is established between an external device and the surface excited device 100 through conductive balls 160 to conductive patterns 132, conductive wires and input and output bond pads 115 of semiconductor die 110.

Referring next to FIG. 2, a surface excited device 200 according to another embodiment of the present invention is illustrated. Since surface excited device 200 as shown in FIG. 2 is similar to surface excited device 100 of FIG. 1A, only those differences between the devices will be described below.

A conductive bump 241 is fused to input and output bond pads 215 formed on a second surface 212 of a semiconductor die 210. Conductive bump 241 may be a conventional gold or solder bump. A hardened conductive paste 242 is formed on the surface of conductive bump 241 and one side of conductive paste 242 is connected to conductive patterns 232 of substrate 230. Thus conductive paste 242 forms an electrical connection to conductive bump 241 providing an electrical connection to semiconductor die 210. The side surfaces of the conductive bump 241 and the conductive paste 242 are flush with side surface 213 of semiconductor die 210 and conductive bump 241 is exposed along the side surface of conductive paste 242.

Conductive paste protects input and output bond pads 215 of semiconductor die 210 and conductive bump 241 from the external environment. Conductive balls 260 may be optionally attached to conductive paste 242 for providing external electrical and mechanical connections or according to the another embodiment of the present invention they may be deleted and surface excited device 200 can be directly connected to an external device directly through conductive paste 242.

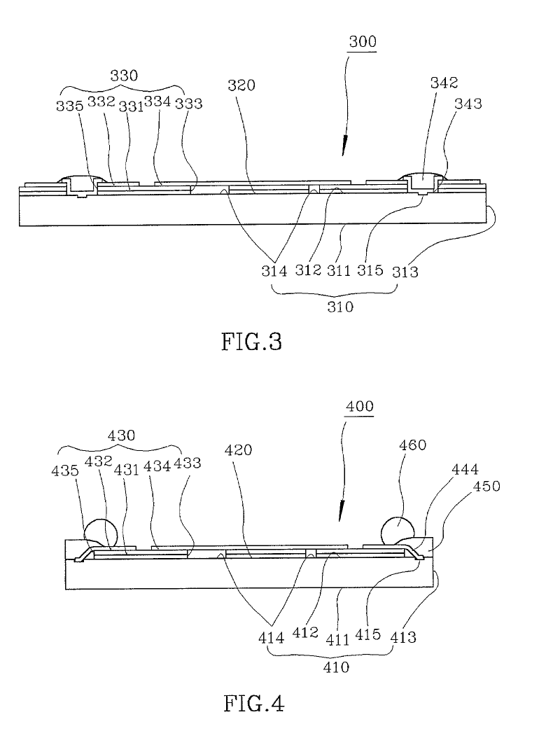

Referring now to FIG. 3, a surface excited device 300 according to another embodiment of the present invention is illustrated. Since surface excited device 300 as shown in FIG. 3 is similar to surface excited device 100 of FIG. 1A, only differences between the devices will be described below.

Substrate 330 is formed at the periphery of input and output bond pads 315 of semiconductor die 310. Accordingly, slot 335 is surrounded by substrate 330. A conductive plating pattern 343 of a predetermined thickness is formed between input and output bond pads 315 and conductive pattern 332 of the substrate 330. Input and output pad 315 and conductive pattern 332 are electrically connected through plating pattern 343.

Plating pattern 343 can be formed by a conventional electrolytic and/or a non-electrolytic plating technique. Alternatively, plating pattern 343 can be formed by a conventional electron ray deposition or sputtering technique and the present invention is not limited by method used to form plating pattern 343. Plating pattern 343 may also be a conventional copper (Cu) or aluminum (Al) pattern. A hardened conductive paste 342 is formed on the surface of plating pattern 343 within slot 335. Conductive ball 360 may be optionally formed on conductive pattern 332 and according to the one embodiment of the present invention no conductive ball 360 is used and the surface excited device 300 is be directly connected to an external device through conductive paste 342.

Referring to FIG. 4, a surface excited device 400 according to another embodiment of the present invention is illustrated. Since surface excited device 400 as shown in FIG. 4 is similar to surface excited device 100 of FIG. 1A, only those differences existing between the devices will be described below.

A lead pattern 444 extends to input and output bond pads 415 of semiconductor die 410 from conductive pattern 432 of substrate 430. Input and output bond pads 415 and the conductive pattern 432 are electrically connected together through lead pattern 444. Lead pattern 444 can be connected to input and output bond pads 415 by a conventional TAB bond or lead bond method and lead pattern 444 can consist of the same material as the conductive pattern 432 or may be fabricated from a different material.

Lead pattern 444 is encapsulated by an encapsulant 450 in order to protect lead pattern 444 from the external environment. A portion of metal pattern 432 and the entire slot 435 of substrate 430 are encapsulated by the encapsulant. Lead pattern 444 is fully covered with the encapsulant 450 similar to the encapsulation of conductive wire 140 as described above.

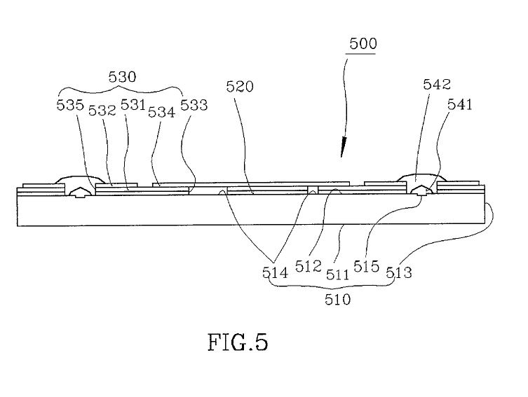

Referring next to FIG. 5, a surface excited device 500 according to another embodiment of the present invention is illustrated. Since surface excited device 500 as shown in FIG. 5 is similar to surface excited device 200 of FIG. 2, only differences between the devices will be described below.

Substrate 530 is formed at a periphery of input and output bond pads 515 of semiconductor die 510. Slot 535 is surrounded by substrate 530 and a hardened conductive paste 542 is formed in slot 535. Conductive bump 541 is fused to input and output bond pads 515 of semiconductor die 510. Conductive ball may be optionally formed on conductive pattern 532 of substrate 530. Alternatively, surface excited device 500 can be directly connected to an external device through conductive paste 542.

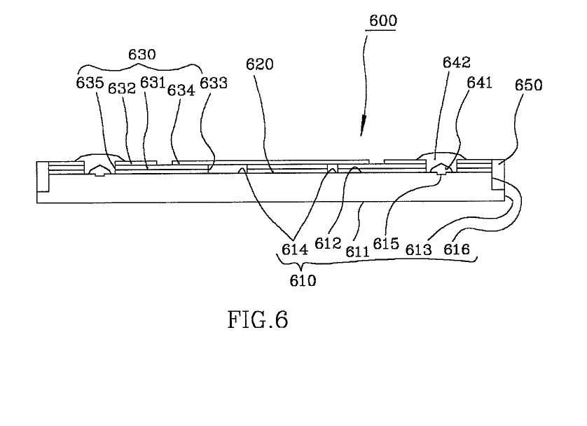

Referring now to FIG. 6, a surface excited device 600 according to another embodiment of the present invention is illustrated. Since surface excited device 600 as shown in FIG. 6 is similar to surface excited device 500 of FIG. 5, only differences existing between the devices will be described below.

An inside surface 616 further formed by machining an upper part of side surface 613 of semiconductor die 610 to a predetermined depth. Inside surface 616 is flush with the side surface of substrate 630. The inside surface 616 of semiconductor die 610 and the side surface of the substrate 630 are surrounded by an encapsulant 650. The side surface of encapsulant 650 is flush with side surface 613 of the semiconductor die 610. The top surface of encapsulant 650 is flush with the top surface of the substrate 630. Although it is not shown in the figure, encapsulant 650 forms a rectangular ring along the edge of the top surface of semiconductor die 610.

Since inside surface 616 is formed at side surface 613 of semiconductor die 610 and is surrounded by the encapsulating portion 650 as described above, water cannot enter the interface between substrate 630 and the semiconductor die 610, preventing de-lamination of the substrate.

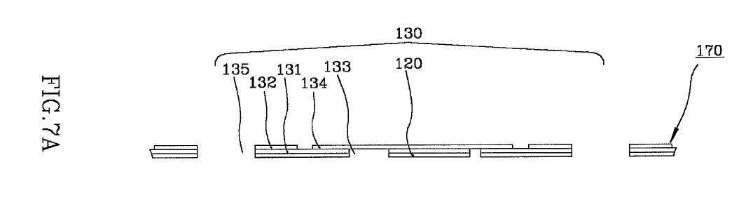

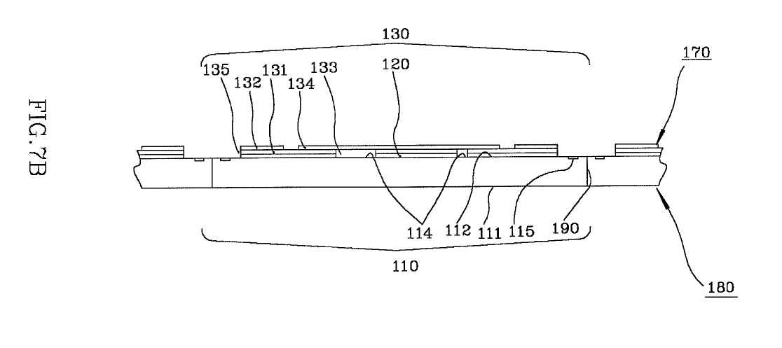

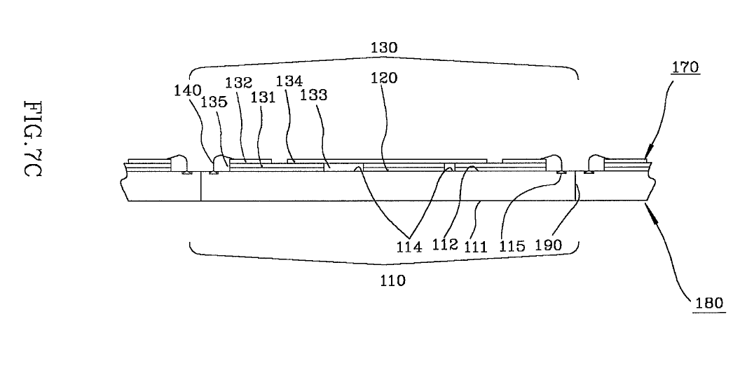

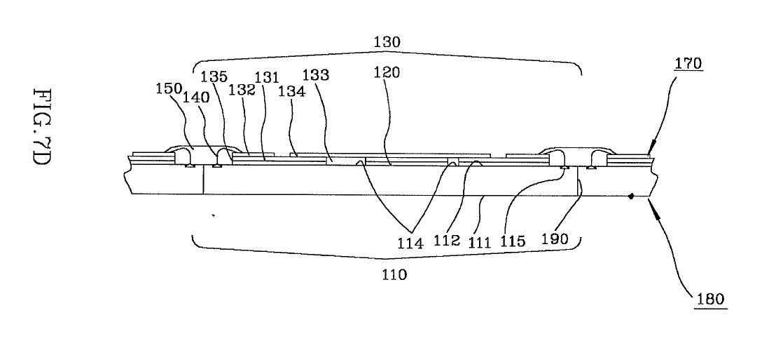

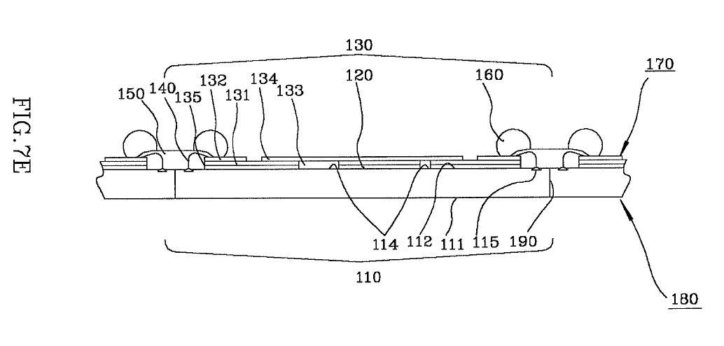

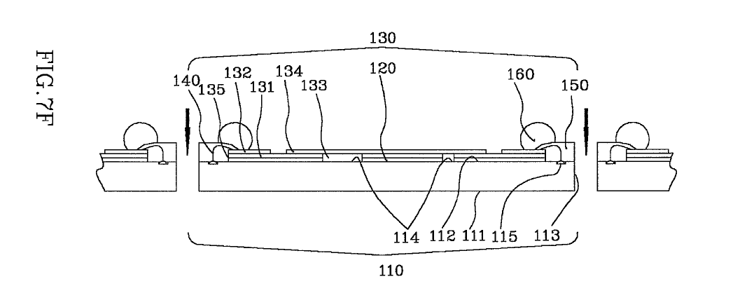

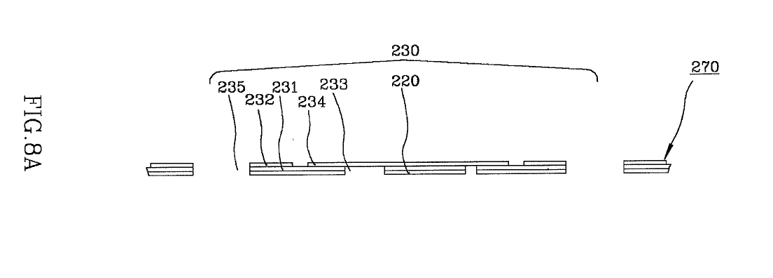

Referring to FIG. 7A through FIG. 7F, a method for packaging a surface excited device of the present invention is illustrated. As shown in FIG. 7A, a substrate strip 170 having a plurality of substrate units 130 connected with a boundary of slots 135 is provided. Substrate unit 130 includes an insulating layer 131, an adhesive 120 bonded to the bottom surface of insulating layer 131, and a plurality of conductive patterns 132 formed on the top surface of insulating layer 131. A cavity 133 is formed at a region corresponding to a surface excited device area 114 of semiconductor die 110, as will be described below, by an aperture formed through the insulating layer 131 and the adhesive 120. Cavity 133 is covered with a cover 134. Adhesive 120 is not a structural element(s) of the substrate strip 170. Adhesive 120 is bonded to the substrate strip 170 during the manufacturing process of the surface excited device.

Next, referring to FIG. 7B, a wafer 180 having a plurality of semiconductor dies 110 connected at a boundary defined by scribing lines 190 is bonded to substrate strip 170 by adhesive 120. The semiconductor die includes a surface excited device area 114 formed by SAW or MEMS techniques and a plurality of input and output bond pads 115 formed at the circumference of surface excited device area 114. The input and output bond pads 115 of each semiconductor die 110 are located inside slot 135 of substrate unit 130. Scribing line 190 is also located at a region under slot 135 of each substrate unit 130. Here, the scribing line 190 shown in the drawing is a phantom line, which is cut to separate the surface excited devices later in the manufacturing process. (In the drawings, reference numeral 111 represents a first surface of each semiconductor die and numeral 112 indicates a second surface of each semiconductor die.)

Next, as shown in FIG. 7C, the input and output bond pads 115 of the semiconductor die 110 are electrically and mechanically connected to conductive patterns 132 of substrate 130 by a conductive wire 140, such as a gold (Au wire) or an aluminum wire (Al wire).

Next, as shown in FIG. 7D, conductive wires 140 are encapsulated by an encapsulant. Conductive wires 140, input and output bond pads 115 and a portion of conductive pattern 132 of substrate 130 are encapsulated by encapsulant 150. Slot 135 of substrate unit 130 is therefore fully filled by encapsulant 150.

Then, as shown in FIG. 7E, a plurality of conductive balls 160, such as solder balls, are fused to each conductive pattern 132 of substrate unit 130. Conductive balls 160 provide external terminals for connecting the surface excited device of the present invention to an external device.

Finally, as shown in FIG. 7F, substrate strip 170 and wafer 180 are sawn along scribing line 190, thereby separating the surface excited devices from substrate strip 170 and wafer 180 to form individual devices. Since encapsulating portion 150 and semiconductor die 110 are sawn together at scribing line 190, side surface 113 of semiconductor die 110 is flush with the side of encapsulating portion 150.

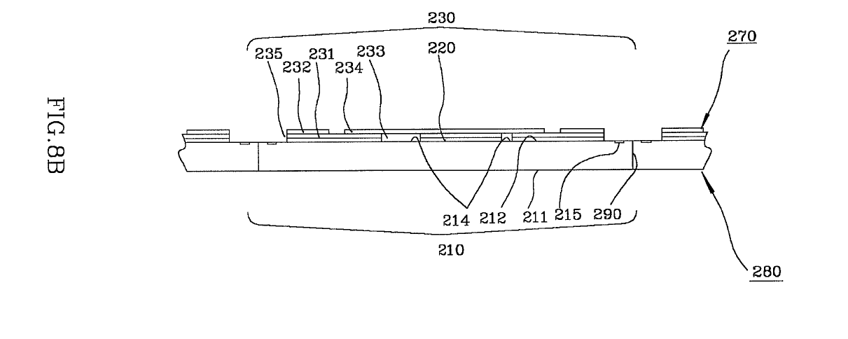

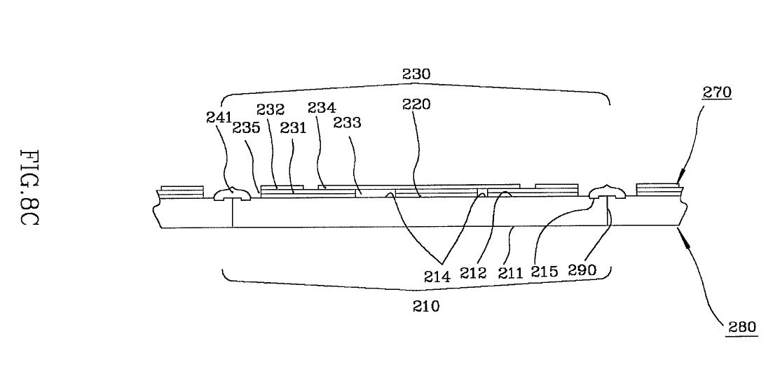

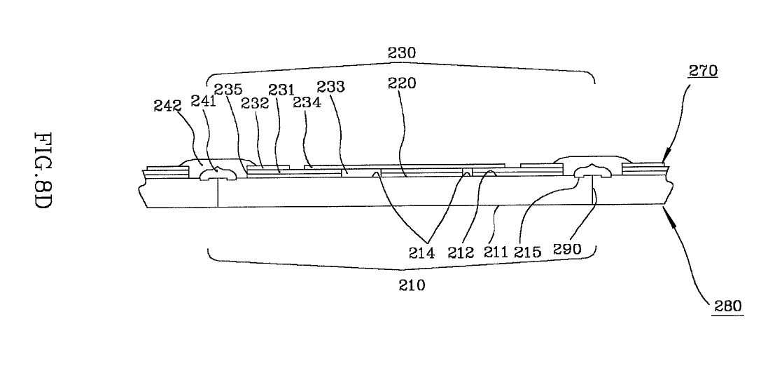

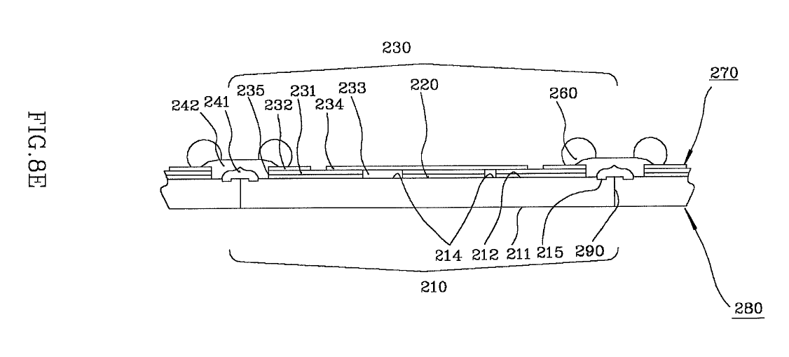

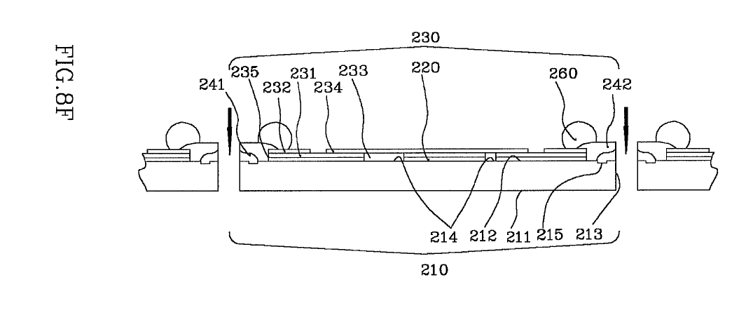

Referring next to FIG. 8A through FIG. 8F, a method for packaging a surface excited device according to another embodiment of the present invention is illustrated.

Since the method for manufacturing a surface excited device of FIG. 8A through FIG. 8F is similar to that of FIG. 7A through FIG. 7F, only those differences existing between the methods will be described below.

First, as shown in FIG. 8A and FIG. 8B, a substrate strip 270 is provided and a wafer 280 is bonded in steps similar to those previously described for the steps illustrated in FIG. 7A and FIG. 7B.

Next, as shown in FIG. 8C, a conductive bump 241 is formed at input and output bond pads 215 of each semiconductor die 210. Conductive bump 241 is fused to input and output bond pads 215 on both sides of scribing line 290. One conductive bump 241 is fused to two input and output bond pads 215 at a time and will be separated later in the manufacturing process. Conductive bump 241 may be a conventional gold or solder bump.

Next, as shown in FIG. 8D, a conductive paste 242 is applied to slot 235 and over the conductive bump 241 and hardened. Conductive paste 242 is hardened through a reflow process, after filling slot 235 with conductive paste 242. Therefore, input and output bond pads 215 of each semiconductor die 210 are electrically connected to conductive pattern 232 of each substrate unit 230 by conductive paste 242.

Next, as shown in FIG. 8E, a plurality of conductive balls 260, such as a solder ball, are fused to conductive patterns 232 of each substrate unit 230. Conductive ball 260 provides an external terminal to connect the surface excited device of the present invention to an external device. Alternatively, the step of fusing conductive balls may be skipped, since conductive paste 242 can be directly connected to the external device.

Finally, as shown in FIG. 8F, substrate strip 270 and wafer 280 are sawn along scribing line 290, separating the individual surface excited devices. Conductive paste 242 and conductive bump 241 are thereby sawn together at scribing line 290. Therefore, side surface 213 of semiconductor die 210 is flush with the side of conductive paste 242 and conductive bump 241. Conductive bump 241 is exposed to the outside under conductive paste 242.

As an alternative, a conductive plating pattern of a predetermined thickness can be formed between input and output bond pads 215 and conductive pattern 232 of substrate unit 230 to electrically connect them (instead of conductive bump 241). Here, the plating pattern can be formed by a conventional electrolytic plating process, a non-electrolytic plating process, an electron ray deposition or sputtering technique or the like.

As a second alternative, a lead pattern of substrate unit 230 can be extended to input and output bond pads 215 of semiconductor die 210 from the conductive pattern 232 of the substrate unit 230. The input and output bond pad 215 and the conductive pattern 232 can be electrically connected to each other through the lead pattern (instead of conductive bumps 241). The lead pattern can be connected to the input and output pads 215 by a conventional TAB bond or a lead bond method.

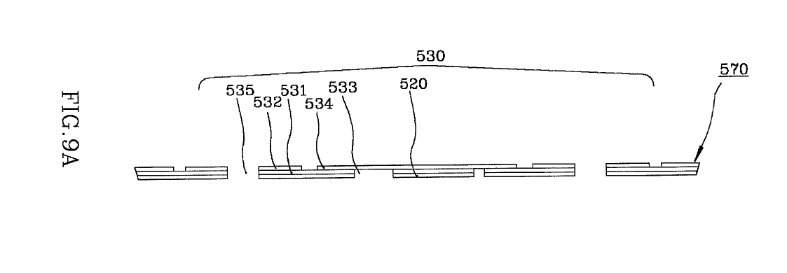

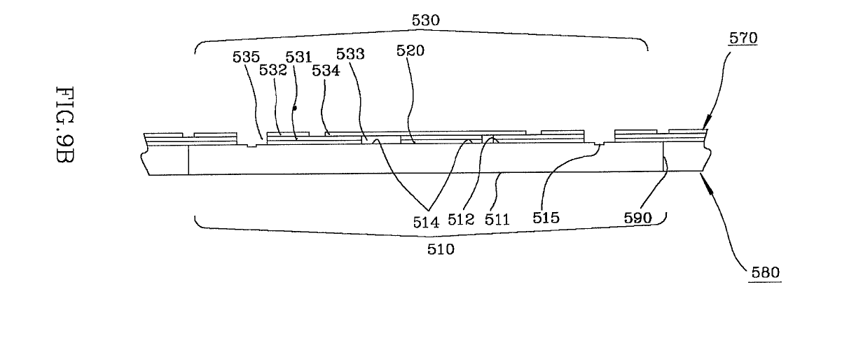

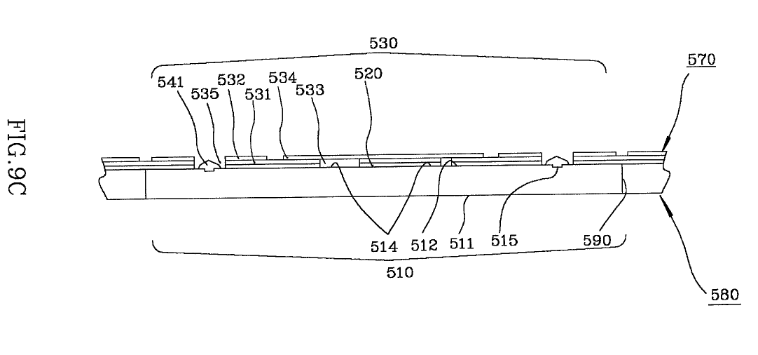

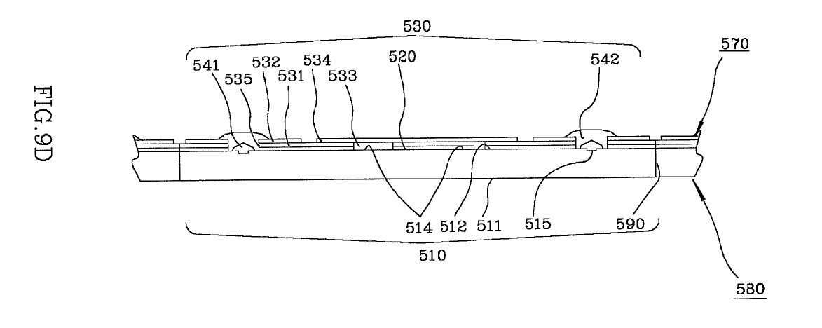

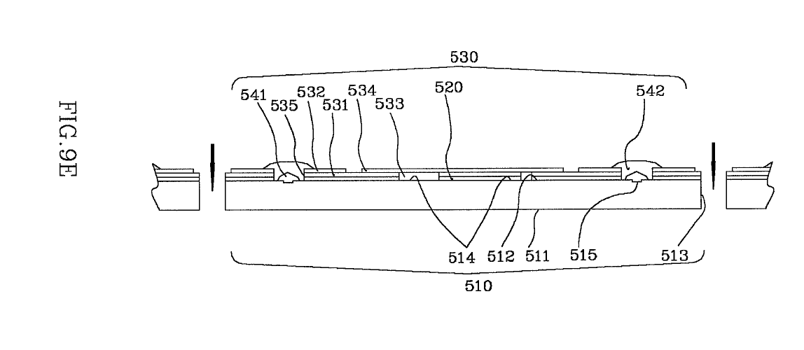

Referring to FIG. 9A through FIG. 9E, a method for packaging a surface excited device according to another embodiment of the present invention is illustrated.

As shown in FIG. 9A, a substrate strip 570 having a plurality of substrate units 530 connected with a boundary of slots 535 is provided. The substrate unit 530 includes a flexible insulating layer 531, an adhesive 520 bonded to the bottom surface of the insulating layer 531, and a plurality of conductive patterns 532 formed on the top surface of the insulating layer 531.

A cavity 533 is formed at a region corresponding to a surface excited device area 514 of each semiconductor die 510, by providing an aperture through insulating layer 531 and the adhesive 520. The cavity 533 is covered with a cover 534.

Next, a wafer 580 having a plurality of semiconductor dies 510 connected with a boundary of scribing lines 590 is bonded to substrate 570 by adhesive 520. Each semiconductor die 510 includes a surface excited device area 514 formed by SAW or MEMS techniques and a plurality of input and output bond pads 515 formed at the circumference of the surface excited device area 514. Scribing line 590 is located outside of slot 535, as opposed to the above-described embodiments.

Then, as shown in FIG. 9C, conductive bumps 541 are fused to input and output bond pads 515 of each semiconductor die 510. Conductive bumps 541 are formed at each of the input and outputs bond pads 515 located within slots 535 of substrate unit 530 using gold or solder or an equivalent.

Next, as shown in FIG. 9D, slots 535 are filled with conductive paste 542 and hardened. Conductive paste 542 is hardened through a reflow process. Input and output bond pads 515 of each semiconductor die 510 are electrically connected to conductive pattern 532 of each substrate unit 530 by conductive paste 542. Conductive paste 542 forms an external terminal to connect separated surface excited devices of the present invention to an external device.

Finally, as shown in FIG. 9E, substrate strip 570 and wafer 580 are sawn along scribing line 590, thereby separating the surface excited devices. Since substrate unit 530 and semiconductor die 510 are sawn together at scribing line 590, side surface 513 of semiconductor die 510 is flush with the side of substrate unit 530.

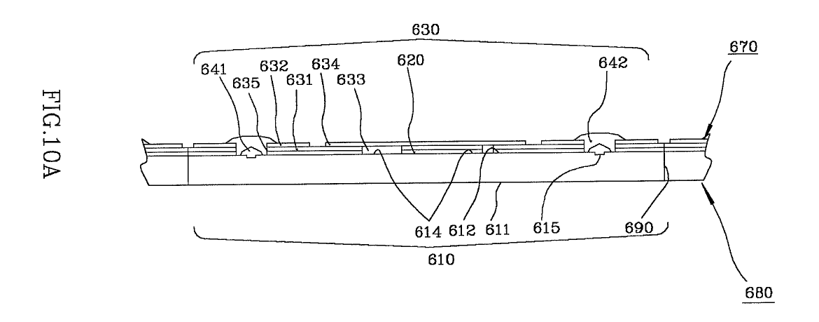

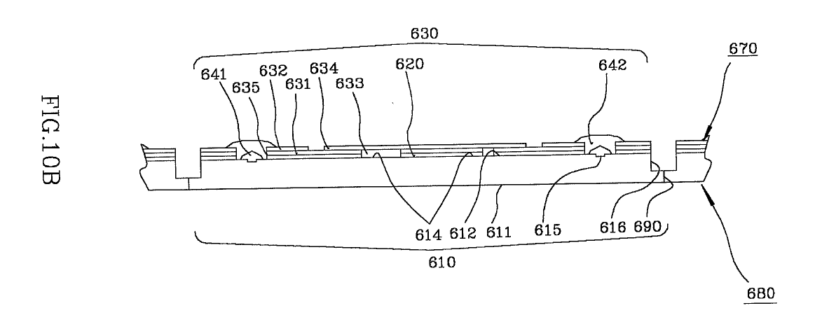

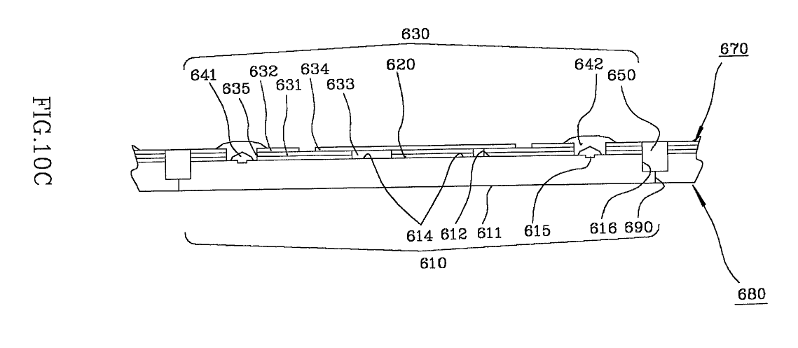

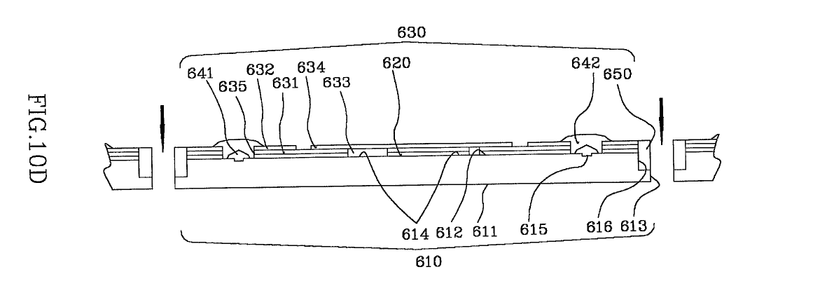

Referring now to FIG. 10A through FIG. 10D, a method for packaging a surface excited device according to another embodiment of the present invention is illustrated.

First, as shown in FIG. 10A, a surface excited device is provided. Since the method for manufacturing the surface excited device is similar to that of FIG. 9A through FIG. 9D, further description of prior steps is omitted here.

Next, as shown in FIG. 10B, a wafer 680 is sawn along scribing line 690 to a predetermined depth by using a blade (not shown) having a predetermined thickness. Scribing line 690 of the wafer 680 and the portion of substrate strip 670 that overlaps scribing line 390 are sawn. An inside surface 616 is thus formed at the side surface of each semiconductor die 610 to the inside of scribing line 690.

Then, as shown in FIG. 10C, an encapsulant 650 is applied within the sawn region, covering each inside surface 616 of the wafer 680. The top surface of the encapsulant 650 is flush with the top surface of substrate strip 670.

Finally, as shown in FIG. 10D, encapsulant 650 and the wafer 680 are sawn through along the scribing line 690, thereby separating the surface excited devices into individual packages. The thickness of the blade used to make the cuts of FIG. 10D is much thinner than the thickness of the blade used to make the cuts of FIG. 10B.

This disclosure provides exemplary embodiments of the present invention. The scope of the present invention is not limited by these exemplary embodiments. Numerous variations, whether explicitly provided for by the specification or implied by the specification, such as variations in structure, dimension, type of material and manufacturing process may be implemented by one of skill in the art in view of this disclosure.

What is claimed is:

1. A surface excited device, comprising:
a semiconductor die having substantially planar first and second surfaces, wherein the second surface includes a surface excited device area, and wherein the semiconductor die further includes a plurality of electrical terminals;
a substrate bonded to the second surface of the semiconductor die by an adhesive, wherein the substrate comprises a plurality of conductive patterns, and further defines a cavity having a predetermined height over the surface exited device area; and
a plurality of conductive connectors for connecting the conductive patterns of the substrate to the electrical terminals of the semiconductor die.

2. The surface excited device package of claim 1, wherein the substrate comprises:
an insulating layer having the conductive patterns formed on a surface thereof and defining an aperture forming the sides of the cavity; and
a cover for covering the aperture, thereby forming the top of the cavity.

3. The surface excited device package of claim 2, wherein the insulating layer is a polyimide film and the conductive patterns are formed from a metal foil layer bonded to the polyimide film.

4. The surface excited device package of claim 1, wherein the surface excited device area is a surface acoustic wave (SAW) device.

5. The surface excited device package of claim 1, wherein the surface excited device area is a micro-electromechanical system (MEMS) device.

6. The surface excited device package of claim 1, wherein the substrate and the adhesive define slots over the electrical terminals of the semiconductor die to provide access to the electrical terminals for the conductive connectors, and wherein the substrate and the semiconductor die have matching length and width except in the region of the slots.

7. The surface excited device package of claim 5, wherein the slots are filled with an encapsulant.

8. The surface excited device package of claim 1, wherein the substrate and the adhesive are smaller than the semiconductor die on at least one side, whereby the electrical terminals of the semiconductor die are exposed to provide access to the electrical terminals for the conductive connectors.

9. The surface excited device package of claim 1, wherein the conductive connectors comprise conductive wires bonded between the electrical terminals of the semiconductor die and the conductive patterns of the substrate, and wherein the conductive wires are encapsulated by an encapsulant.

10. The surface excited device package of claim 1, wherein the conductive connectors comprise conductive bumps fused to the electrical terminals of the semiconductor die, and further comprising a hardened conductive paste applied between the conductive bump and the conductive patterns.

11. The surface excited device package of claim 1, wherein the conductive connectors are conductive plating patterns formed between the electrical terminals of the semiconductor die and the conductive patterns of the substrate.

12. The surface excited device package of claim 1, wherein the conductive connectors are extensions of the conductive patterns of the substrate extending to the electrical terminals of the semiconductor die.

13. The surface excited device package of claim 12, wherein the extensions of the conductive patterns are encapsulated by an encapsulant.

14. The surface excited device package of claim 1, further comprising a plurality of conductive balls fused to the conductive patterns of the substrate for connecting the surface excited device package to an external device.

15. The surface excited device package of claim 1, wherein the sides of the semiconductor die and the first surface of the semiconductor die are exposed to the outside of the package.

16. The surface excited device package of claim 1, wherein the side of the semiconductor die include a step, and wherein the substrate extends to the inner edge of the step, and wherein the step is filled by an encapsulant to protect the sides of the substrate from the external environment.

17. A surface excited device, comprising:
a semiconductor die having substantially planar first and second surfaces, wherein the second surface includes a surface excited device area, and wherein the semiconductor die further includes a plurality of electrical terminals;
a substrate comprising a plurality of conductive patterns, and wherein the substrate is bonded to the second surface of the semiconductor die;
means for connecting the conductive patterns of the substrate to the electrical terminals of the semiconductor die; and
means for permitting mechanical vibration of the surface excited device area while the substrate is bonded to the second surface of the semiconductor die.

18. The surface excited device of claim 17, wherein the permitting means further comprises means for covering the surface excited device area to protect the surface excited device area from the external environment.

19. A method for packaging a surface excited device, comprising:
bonding a semiconductor die having a surface excited device area to a substrate having a plurality of conductive patterns and defining a cavity having a predetermined height over the surface exited device area; and
attaching a plurality of conductive connectors to connect the conductive patterns of the substrate to the electrical terminals of the semiconductor die.

20. The method of claim 19, wherein the substrate comprises an insulating layer having the conductive patterns formed on a surface thereof and wherein the method further comprises:
forming the cavity in the substrate by forming an aperture in the insulating layer; and
a covering the aperture above the insulating layer, thereby forming the top of the cavity.

21. The method of claim 19, further comprising forming slots in the substrate at positions corresponding the electrical terminals of the semiconductor die to provide access to the electrical terminals for the conductive connectors.

22. The method of claim 21, further comprising the step of applying an encapsulant over the slots for filling the slots.

23. The method of claim 19, wherein the step of connecting is performed by applying conductive paste applied between conductive bumps on the semiconductor die and the conductive patterns.
